(19) United States
(12) Patent Application Publication
(10) Pub. No.: US 2002/0086561 A1
(43) Pub. Date: Jul. 4, 2002

(54) Wiring board

(75) Inventors: Kouki Ogawa, Ichinomiya-shi (JP); Yasuhiro Sugimoto, Kohnan-shi (JP)

Correspondence Address: SUGHRUE MION, PLLC, 2100 Pennsylvania Avenue, NW, Washington, DC, 20037-3213, US

(73) Assignee: NGK SPARK PLUG CO., LTD.

(21) Appl. No.: 10/012,312

(22) Filed: Dec. 12, 2001

(30) Foreign Application Priority Data
Dec. 28, 2000 (JP) 2000-402498
Dec. 12, 2000 (JP) 2000-377926

(51) Int. Cl. H05K 1/00

(52) U.S. Cl. 439/55

(57) ABSTRACT

A wiring board simplifying connection of electronic parts mounted on a principal face side of the wiring board and chip capacitors mounted on a reverse face side thereof in such a manner that the wiring board 100 mounting the chip capacitors 160 on a reverse face 101c-side comprises bumps 129 capable of being connected to IC chip 10, first and second capacitor connecting pads 149p, 149g connecting the upper face parts 163 of the chip capacitors 160, a plurality of insulating layers 121, 111, 141 intervening the first and the second capacitor connecting pads, and first and second converting-conductor layers 146p, 146g in stripe pattern formed at interlayer 152, connected to the bumps 129 at the principal face 101b-side, connected to the first capacitor connecting pads 149p at the reverse face 10c-side or the second capacitor connecting pads 149g for changing the connecting positions or the connecting number at the principal face side and the reverse face side.

### TECHNICAL FIELD OF THE INVENTION

The present invention relates to a wiring board for mounting electronic parts, and in particular to a wiring board mounting chip capacitors on a reverse face side.

### BACKGROUND OF THE INVENTION

IC chips has become higher speed in actuation owing to progress of technique of integrated circuit, and being accompanied therewith, noises are accumulated on such as wiring of electric source and bring about erroneous actuation. For removing noises, for example, as seen in FIG. 16, a wiring board 2 mounting IC chip 1 thereon is separately mounted with chip capacitors 3 on a principal face 2b or a reverse face 2c, and capacitor-connecting wiring 4 is provided within the wiring board for respectively connecting two electrodes of the capacitors 3. Thereby, the chip capacitors 3 are connected to a source terminal or an earth terminal of IC chip 1 via the capacitor-connecting wiring 4 and flip-chip pad 5.

However, depending on the above technique, the capacitor-connecting wires 4 connected to the chip capacitors 3 are drawn around within the wiring board 2. When changing positions of terminals of IC chip 1, it has been necessary to re-design a whole wiring including the capacitor-connecting wires 4. Especially, IC chip of high integration degree is often formed with lots of source terminals and earth terminals, and the drawing-around is easily subject to complication. In addition, in case of mounting many chip capacitors or connecting the chip capacitors having many terminals, the drawing-around also becomes complicated.

### SUMMARY OF THE INVENTION

The invention has been accomplished in view of these problems, and it is an object of the invention to provide a wiring board making ready for connecting electronic parts mounted on the principal face side of the wiring board with chip capacitors mounted on the reverse face side thereof.

Means for solving the problems is a wiring board having a principal face and a reverse face, comprising a plurality of principal-face-side connecting terminals formed on the principal face side and enabling to be connected to respective terminals of electronic parts to be mounted on the principal face side, chip capacitors mounted on the reverse face side furnished with one-side electrodes and other-side electrodes composing capacitors, at least one of the chip capacitors having a first face facing to the reverse face, at least one of first terminals formed on the first face and connected to the one-side electrodes, and at least one of second terminals formed on the first face and connected to the other-side electrodes, first capacitor-connecting terminals formed on the reverse face side and connected to the respective first terminals of the chip capacitors, second capacitor-connecting terminals formed on the reverse face side and connected to the respective second terminals of the chip capacitors, a plurality of insulating layers interposed among the principal-face-side connecting terminals, the first capacitor-connecting terminals, and the second capacitor-connecting terminals, at least one of first converting-conductor layers formed at specific interlayer selected from interlayer of the mutual insulating layers, connected to the plurality of principal-face-side connecting terminals at the principal face side, connected to at least one of first capacitor-connecting terminals at the reverse face side, and changing the connecting positions and the connecting number at the principal face side and the reverse face side, and at least one of second converting-conductor layers formed at the specific interlayer while being insulating the first converting-conductor layers, connected to the plurality of principal-face-side connecting terminals at the principal face side, connected to at least one of second capacitor-connecting terminals at the reverse face side, and changing the connecting positions and the connecting number at the principal face side and the reverse face side.

The wiring board of the invention is formed with the first and the second converting-conductor layers for changing the connecting positions and the connecting number at the principal face side and the reverse face side at the same specific interlayer. The first converting-conductor layers are connected to the principal-face-side connecting terminals at the principal face side, and to the first capacitor-connecting terminals at the reverse face side. Further, the second converting-conductor layers are connected to the principal-face-side connecting terminals at the principal face side, and to the second capacitor-connecting terminals at the reverse face side. Therefore, the connection between the principal-face-side connecting terminals and the first and second capacitor-connecting terminals is easily provided. Accordingly, the connection between terminals of the electronic parts and the first and second terminals is easily made.

As the chip capacitors, any of them are sufficient if being able to be mounted on the wiring board. For example, there are enumerated laminated ceramic types, electrolytic capacitor types, or film capacitor types. In particular, the chip capacitors of the laminated ceramic type have desirable frequency characteristics, and being effected with heat, the characteristics are comparatively stable.

Besides, the first and second terminals formed on the first faces of the chip capacitors are preferably many formed. Because, by forming many, those may be connected in parallel with the first and second converting-conductor layers, and resistance and inductance occurring at wiring between the first, second converting-conductor layers and the chip capacitors may be more reduced. Therefore, the first and second terminals of the chip capacitors are sufficient with those formed on the periphery of the first face, but preferable are such terminals arranged in, e.g., lattice within the first face.

More preferable are that the first terminal and the second terminal are alternately arranged in a manner that, seeing from a certain first terminal, a terminal most approaching this first terminal is a second terminal. The current flowing via the first terminal and the current flowing via the second terminal are opposite to each other with regard to direction when charging and discharging the chip capacitors, and also in this regard, inductance can be decreased.

As the wiring board, there are listed resins such as epoxy resin, polyimide resin, BT resin or PPE resin, composite materials of fibers such as glass fiber or polyester fiber with the resins, or resin composite materials of fluorine resin having three dimensional network structure impregnated with epoxy resin. Further listed are ceramic boards made of alumina, mullite, aluminum nitride or glass ceramic, or combinations of the ceramic board with the resins or composite materials.

Around the principal-face-side connecting terminals and the first and the second capacitor-connecting terminals, solder resist layers may be formed for securing the mutual insulation and preventing solder wetted spread.

In the wiring board as mentioned above, it is preferred that as the specific interlayer, the nearest interlayer to the first capacitor-connecting terminals and the second capacitor-connecting terminals among the interlayer of the mutual insulating layers are selected, and the number of the principal-face-side connecting terminals connected to any of the first converting-conductor layers and the second converting-conductor layers of the principal-face-side connecting terminals is more than the sum of the number of the first capacitor-connecting terminals connected to the first converting-conductor layers + (plus) the number of the second capacitor-connecting terminals connected to the second converting-conductor layers.

The wiring of connecting the principal-face-side connecting terminals and the first, second capacitor-connecting terminals (the first and the second terminals of the chip capacitors) can restrain resistance value and inductance, the more the parallel paths. Accordingly, seeing from the first and the second converting-conductor layers, a comparison is made between the number of the principal-face-side connecting terminals connecting therewith and the number of the first and the second capacitor-connecting terminals (the sum of the number of the first capacitor-connecting terminals + (plus) the number of the second capacitor-connecting terminals), and if shortening the wiring of the less number side, the wiring is advantageous with respect to resistance and inductance. Therefore, in case the number of the principal-face-side connecting terminals connected to the first and the second converting-conductor layers is more than the number of the first and the second capacitor-connecting terminals, it is desirable to dispose the first and the second converting-conductor layers as near as possible to the first and the second capacitor-connecting terminals, that is, near to the chip capacitors.

Since the invention selects as the specific interlayer the nearest interlayer to the first capacitor-connecting terminals and the second capacitor-connecting terminals among the interlayer of the mutual insulating layers, there are accordingly nearest disposed the first and the second converting-conductor layers and the first and the second capacitor-connecting terminals. It is possible thereby to reduce resistance and inductance between the principal-face-side connecting terminals and the first, second terminals of the chip capacitors.

In the case of the wiring board mounting IC chips of high integration, the number of the principal-face-side connecting terminals is often many. In IC chips of high integration, lots of source terminals and earth terminals are equipped. Therefore, for mounting IC chips of high integration, it is preferable to apply the invention.

The wiring board is any of the mentioned above, and at least one parts of the first capacitor-connecting terminals connected with the first converting-conductor layers at the reverse face side are positioned within such a range of projecting the connected first converting-conductor layers onto the first face, the first capacitor-connecting terminals and the first converting-conductor layers are connected through bear conductors passing the insulating layers, at least one parts of the second capacitor-connecting terminals connected to the second converting-conductor layers at the reverse face side are positioned within such a range of projecting the connected second converting-conductor layers onto the first face, and the second capacitor-connecting terminals and the second converting-conductor layers are connected through the bear conductors passing the insulating layers.

In the wiring board of the invention, of the chip capacitors, at least one parts of the first capacitor-connecting terminals connected to the first converting-conductor layers are positioned within the range of projecting the connected first converting-conductor layers onto the first face. Reversely to say, seeing from a certain first capacitor-connecting terminal, the first converting-conductor layers connecting thereto positions perpendicularly on the principal face side. The first capacitor-connecting terminals and the first converting-conductor layers are connected through the bear conductors having lower resistance and lower inductance than those of wiring layers formed between the insulating layers, specifically through the bear conductors passing the insulating layers toward the reverse face side from the first converting-conductor layers and extending vertically. Thus, the first capacitor-connecting terminals and the first converting-conductor layers may be connected at low resistance and low inductance.

Similarly, at least one parts of the second capacitor-connecting terminals connected to the second converting-conductor layers at the reverse face side are positioned within the range of projecting the connected second converting-conductor layers onto the first face of the chip capacitors. Reversely to say, seeing from a certain second capacitor-connecting terminal, the second converting-conductor layers connecting thereto positions perpendicularly on the principal face side. The second capacitor-connecting terminals and the second converting-conductor layers are connected through the bear conductors passing the insulating layers toward the reverse face side from the first converting-conductor layers and extending vertically. Thus, the second capacitor-connecting terminals and the second converting-conductor layers may be also connected at low resistance and low inductance.

Further, another means for solving the problem is a wiring having a principal face and a reverse face, comprising a plurality of principal-face-side connecting terminals formed on the principal face side and enabling to connect with respective terminals of electronic parts mounted on the principal face, chip capacitors mounted on the reverse face side furnished with one-side electrodes and other-side electrodes composing capacitors, at least one of the chip capacitors having a first face facing to the reverse face, at least one of first terminals formed on the first face and connected to the one-side electrodes, and at least one of second terminals formed on the first face and connected to the other-side electrodes, at least one insulating layer interposed between the principal-face-side connecting terminals and first and second terminals of the chip capacitors, at least one of first converting-conductor layers formed on the reverse face of most-reverse face side insulating layers positioned on the most reverse face side among the insulating layers, connected to the plurality of principal-face-side connecting terminals at the principal face side, connecting directly or via conductive connecting materials with at least one of first terminals at the reverse face side, and changing the connecting positions and the connecting number at the principal face side and the reverse face side, and at least one of second converting-conductor layers formed at the reverse face side of the most-reverse face side insulating layers while being insulating the first converting-conductor layers, connected to the plurality of principal-face-side connecting terminals at the principal face side, connecting directly or via the conductive connecting materials with at least one of second terminals at the reverse face side, and changing the connecting positions and the connecting number at the principal face side and the reverse face side.

The wiring board of the invention is formed at the reverse face side of the most-reverse face side insulating layers with the first and the second converting-conductor layers for changing the connecting positions and the connecting number at the principal face side and the reverse face side. The first converting-conductor layers are connected to the principal-face-side connecting terminals at the principal face side and to the first terminals of the chip capacitors at the reverse face side. Further, the second converting-conductor layers are connected to the principal-face-side connecting terminals at the principal face side and to the second terminals of the chip capacitors at the reverse face side. Therefore, the connection between the principal face side terminals, and the terminals of the electronic parts and the first and second terminals is easily made.

Besides, the first and the second converting-conductor layers are formed at the reverse face side of the most-reverse face side insulating layers of the insulating layers between the principal-face-side connecting terminals and the first, second terminals of the chip capacitors. So, the first and the second terminals of the chip capacitors and the first and the second converting-conductor layers become nearest, so that resistance and inductance occurring therebetween can be most reduced.

The first and second converting-conductor layers are connected to the first and the second terminals of the chip capacitors directly or via the conductive connecting materials, not via the bear conductors. Therefore, resistance and inductance created by the connection the first and the second terminals of the chip capacitors and the first and the second converting-conductor layers can be most reduced.

By the way, as the conductive materials, a solder or a conductive adhesive may be taken up. The solder may be selected taking material quality of the wiring board or the first and the second terminals into consideration, for example, there are Pb-Sn based or Sn-Sb based solders. As the conductive adhesive, for example, there are those dispersed in resins as epoxy resin with conductive fillers comprising carbon powder, metallic powder as silver, copper or nickel, resin particles covered with these metals, or glass particles.

The wiring board is as mentioned above, and the number of the principal-face-side connecting terminals connected to any of the first converting-conductor layers and the second converting-conductor layers of the principal-face-side connecting terminals is more than the sum of the number of the first terminals connected to the first converting-conductor layers + (plus) the number of the second terminals connected to the second converting-conductor layers.

The wiring of connecting the principal-face-side connecting terminals and the first, second terminals of the chip capacitors can restrain resistance value and inductance, the more the parallel paths. Accordingly, seeing from the first and the second converting-conductor layers, a comparison is made between the number of the principal-face-side connecting terminals connected to these converting-conductor layers and the number of the first and the second capacitor-connecting terminals, and if shortening the wiring of the less number side, the wiring is advantageous with respect to resistance and inductance. Therefore, in case the number of the principal-face-side connecting terminals connected to the first and the second converting-conductor layers is more than the number of the first and the second terminals, it is desirable to dispose the first and the second converting-conductor layers as near as possible to the first and the second terminals, that is, near to the chip capacitors.

In the invention, as mentioned above, the first and the second converting-conductor layers are formed at the reverse face side of the most-reverse face side insulating layers, and are connected to the first and the second terminals of the chip capacitors directly or via the conductive connecting materials, so that the first, second converting-conductor layers and the first, second terminals of the chip capacitors are disposed at the especially near position. Therefore, resistance and inductance between the principal-face-side connecting terminal and the first, second terminals of the chip capacitors can be particularly reduced.

In the case of the wiring board mounting IC chips of high integration, the number of the principal-face-side connecting terminals is often many. Because in IC chips of high integration, lots of source terminals and earth terminals are equipped. Therefore, for mounting IC chips of high integration, it is preferable to apply the invention.

The wiring board is any of the mentioned above, and the first converting-conductor layers and the second converting-conductor layers have parts of stripe patterns alternately arranged.

Of the connecting terminals of electronic parts as IC chip and the principal-face-side connecting terminal in response thereto, those connected to the first terminals of the chip capacitors (for example, those connected to source potential) and those connected to the second terminals (for example, those connected to earth potential) are near and often designed and disposed for parallel parts.

In contrast, the wiring board of the invention has the striped pattern parts in the first and the second converting-conductor layers. In the striped pattern parts, since the first and the second converting-conductor layers are adjacent, the principal-face-side connecting terminal extend the connecting wires by use of the bear conductors toward the reverse face side in response to the terminals (either of the first terminals and the second terminals) of the chip capacitors, and as needed, the short wiring is formed between the mutual insulating layers so as to adjust the positions for connected to the objective first or second converting-conductor layers. In short, in the striped pattern parts, it is possible to easily connect the principal-face-side connecting terminal with any of the first and the second converting-conductor layers, and the wiring is ready for designing.

In particular, when the first and the second terminals are disposed alternately in the chip capacitors, the first terminals of the chip capacitors can be easily connected to the first converting-conductor layers in the striped pattern parts, while the second terminals of the chip capacitors can be easily connected to the second converting-conductor layers, thereby to make the wiring design easy. Besides, if the first and the second terminals of the chip capacitors are alternately arranged, inductance can be restrained and such arrangement is preferable to the current flowing, since inductance can be lowered by the opposite directions of the currents output from and input in the chip capacitors.

Further, the wiring board is as mentioned above, and the first converting-conductor layers and the second converting-conductor layers have parts where directions of current flowing when charging and discharging the chip capacitors are opposite to each other in the stripe pattern.

The wiring board of the invention has the currents-reverse-flowing parts, and in this part, the currents flowing directions are revered when charging and discharging the chip capacitors and cancel magnetic fields each other (negative mutual inductance occurs) Therefore, in this part, inductance is more restrained and as a whole inductance can be more lowered.

### BRIEF DESCRIPTION OF THE DRAWINGS

FIG. 1 is a cross sectional view of the wiring board according to the embodiment 1;

FIG. 2 is an explanatory view showing potentials of the respective terminals of the chip capacitors arranged longitudinally and latitudinally;

FIG. 3 is an explanatory perspective view showing conditions of the chip capacitors arranged longitudinally and latitudinally and directions of the current flowing along the sides thereof;

FIG. 4 is an explanatory view showing the relation between the converting-conductor layers and the respective terminals of the chip capacitors;

FIG. 5 is an explanatory view showing the relation among the converting-conductor layers, the bear conductors connected to the converting-conductor layers from the principal face side and the respective terminals of the chip capacitors;

FIG. 6 is another cross sectional view of the wiring board according to the embodiments 1 and 2;

FIG. 7 is an explanatory view showing the mutual relation of the current flowing along the adjacent converting-conductor layers according to the embodiments 1 and 2;

FIG. 8 is an explanatory view showing the relation between the converting-conductor layers and the respective terminals of the chip capacitors in the wiring board according to a modified embodiment 1;

FIG. 9 is an explanatory view showing the relation between the converting-conductor layers and the respective terminals of the chip capacitors in the wiring board according to a modified embodiment 2;

FIG. 10 is an explanatory view showing the relation between the converting-conductor layers and the respective terminals of the chip capacitors in the wiring board according to a modified embodiment 3;

FIG. 11 is an explanatory view showing the relation between the converting-conductor layers and the respective terminals of the chip capacitors in the wiring board according to a modified embodiment 4;

FIG. 12 is an explanatory view showing the relation between the converting-conductor layers and the respective terminals of the chip capacitors in the wiring board according to a modified embodiment 5;

FIG. 13 is a cross sectional view of the wiring board according to the embodiment 2;

FIG. 14 is another cross sectional view of the wiring board according to the embodiment 2;

FIG. 15 is an explanatory view showing the relation between the converting-conductor layers and the respective terminals of the chip capacitors according to the embodiment 2; and

FIG. 16 is an explanatory view showing the conventional wiring board mounting the chip capacitors on the principal face and the reverse face of the board.

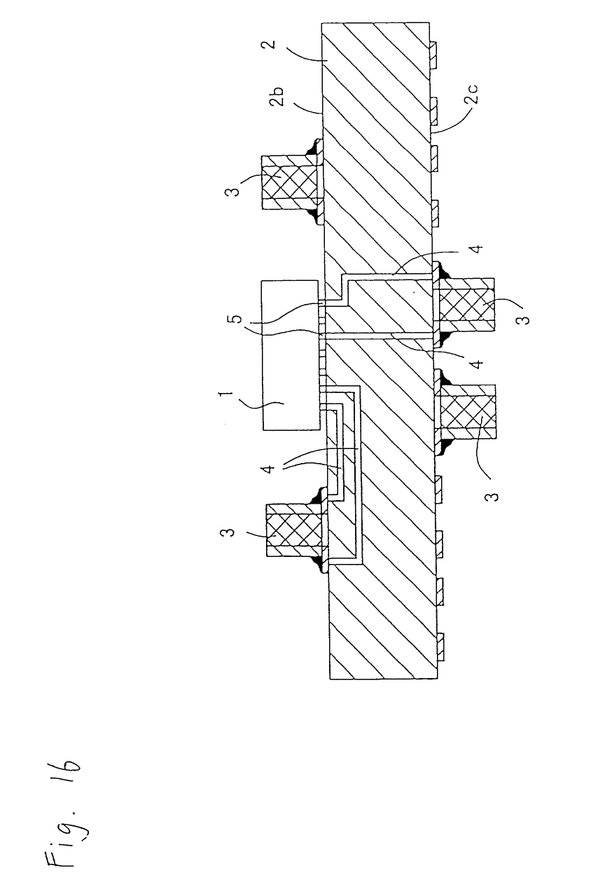

In the drawings, reference numerals 100 and 800 designate the wiring boards. 101 and 801 are the wiring board main bodies. 101b and 801b are principal faces. 101c and 801c are reverse faces. 110 and 810 are core boards. 111 and 811 are core board main bodies (insulating layers). 112,113, 812 and 813 are through hole conductors. 121 and 821 are principal face side resin insulating layers (insulating layers). 122, 142, 822 and 842 are solder resist layers. 127 and 827 are bear conductors. 128 and 828 are pads. 129 and 829 are bumps (principal-face-side connecting terminal). 141 is a reverse face side insulating layers (insulating layer). 841 is a reverse face side insulating layers (most-reverse face side insulating layer). 146, 246, 346, 446, 546, 646 and 849 are converting-conductor layers. 146p, 246p, 346p, 446p, 546p, 646p and 849p are first converting-conductor layers. 146g, 246g, 346g, 446g, 546g, 646g and 849g are second. 149p is a first capacitor connecting pad (first capacitor-connecting terminals). 149g is a second capacitor connecting pad (second capacitor-connecting terminals). 152 is interlayer (specific interlayer). 151, 153, 154, 851, 852, 853 and 854 are interlayer. 160, 360 and 560 are chip capacitors. 160u, 360u and 560u are upper faces of chip capacitors (first face). 161, 361 and 561 are chip capacitor main bodies. 161u, 361u and 561u are upper faces of chip capacitor main bodies. 161s and 361s are side faces of chip capacitor main bodies. 161e and 161f are electrode layers (electrodes). 162 and 362 are capacitor terminals. 163b and 363b are upper face parts (first terminals). 163c and 363c are upper face parts (second terminals). 164b and 164c are side face parts. 165b and 165c are under face parts. 563b is a terminal (first terminal). 563c is a terminal (second terminal). 41 is currents-reverse- flowing part.

### DETAILED DESCRIPTION OF THE INVENTION

(Embodiment 1)

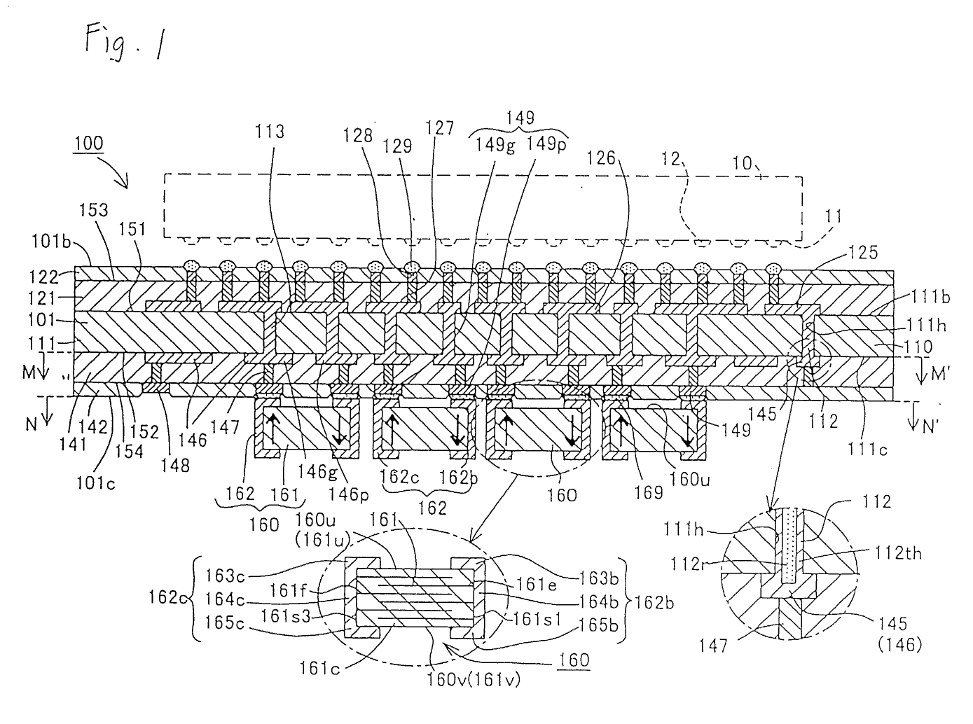

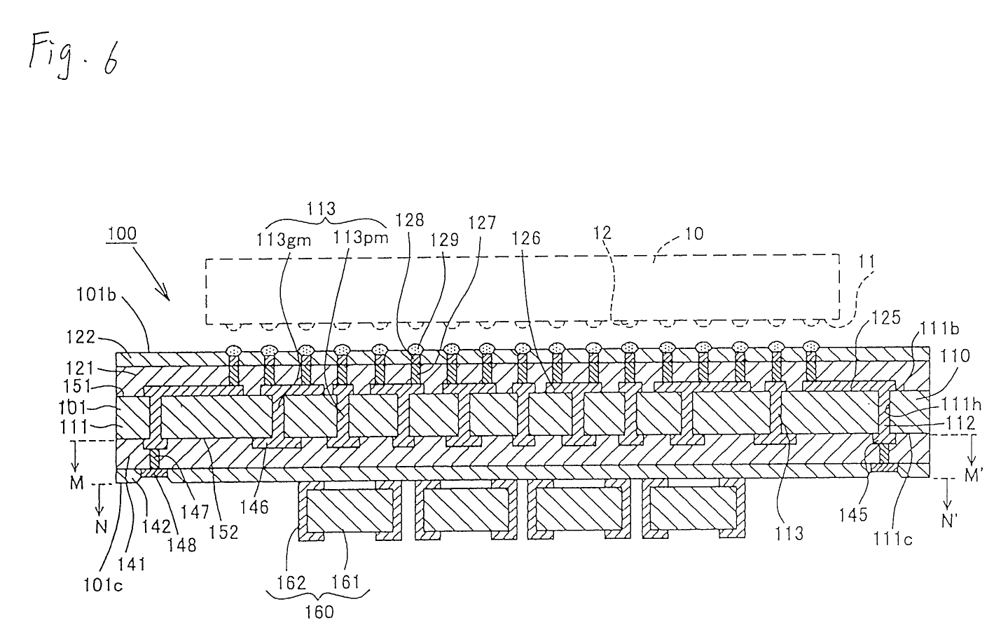

A first embodiment of the invention will be explained, referring to FIGS. 1 to 7. The wiring board 100 shown in FIGS. 1 and 6 comprises a wiring board main body 101 and the chip capacitors 160 mounted on a reverse face 101c. The wiring board 101 has a core board 110, a principal face side resin insulating layer 121 made of epoxy resin and a solder resist layer 122 laminated on the upper surface of the core board 110, a reverse face side resin insulating layer 141 and a solder resist layer 142 laminated on the lower surface of the core board 110. On the center part of the principal face 101b of the wiring board main body 101, lots of bumps 129 are formed, and the lots of bumps 129 can make flip-chip connections with many connecting terminals 12 formed on the under surface 11 of IC chip 10 shown with an imaginary line. On the center part of the reverse face 101c, lots of capacitor connecting pads 149 (the first and the second converting-conductor layers 149p, 149g) are formed on which the chip capacitors 160 are many mounted via solders 169. At the periphery of the reverse face 101c, connecting pads 148 are formed enabling to be connected to respective terminals many formed on other wiring board such as a mother board (not shown).

The core board 110 has a core board main body 111 made of a composite material of glass-epoxy resin being a rectangular plate of 31 mm×31 mm×1.0 mm thick. Between an upper surface 111b and a lower surface 111c, many through hole penetrating holes 111h are bored passing there through. At the interiors of the through hole penetrating holes 111h, known through hole conductors 112, 113 are defined.

The bumps 129 formed on the principal face 101b are connected to wiring layers 125, 126 formed on the upper surface 111b of the core board main body 111 (interlayer 151 of the core board main body 111 and the principal face side resin insulating layer 121) via pads 128 opening to the solder resist layer 122 and the bear conductors 127 penetrating the principal face side resin insulating layer 121.

Specifically, the bumps 129 positioned almost on the peripheral part are connected to the wiring layers 125 through pads 128 and the bear conductors 127, fan out to the peripheral side (the right or left directions in FIGS. 1 and 6), connect with the through hole conductors 112 positioned on the peripheral part and further connect with the connecting pads 148 exposed from the solder resist layer 142 via the wiring layers 145 formed in the reverse face 111c (the interlayer 152 between the core board main body 111 and the reverse face side resin insulating layer 141) and the bear conductors 147. These members are mainly served as wiring for signals, and sometimes served as source wiring for supplying +source potential and earth potential.

For reducing resistance and inductance occurring in the bear conductors 147, the reverse face side resin insulating layer 141 and the connecting pads 148 are preferably connected via a plurality of bear conductors 147.

On the other hand, the bumps 129 positioned almost on the center do not fan out, but adjust the positions by use of the wiring layers 126 formed at the interlayer 151, otherwise converge the wires (the bear conductors) from the plural bumps 129, that is, connect in parallel them, and connect with the through hole conductors 113 positioning at the center. In comparison with the distance between the bumps 129 (for example, minimum 150 μm), the distance between the through hole conductors 113 (for example, minimum 600 μm) is preferably larger.

Further, the bumps 129 are connected to the converting-conductor layers 146 formed at the lower plane 111c (the interlayer 152) of the core board 111 and connected to capacitor-connecting pads 149 exposed from the solder resist layer 142 via the bear capacitors 147 passing the reverse face side resin insulating layer 141. Accordingly, electrodes 162 (162b, 162c) of the capacitors 160 and the bumps 129 are connected.

As seen at the left side of FIG. 1, some of the connecting pads 148 positioning on the periphery of the reverse face 101c pass the bear conductors 147 and connect with the converting-conductor layers 146, and through such courses, the +source potential and earth potential are supplied respectively into the bumps 129 and the chip capacitors 160 at the center part. Otherwise, through the course of the connecting pad 148, the bear conductor 147, the wiring layer 145, the through hole conductor 112, and the wiring layers 125, 126, the +source potential and the earth potential can be also supplied respectively into the bumps 129 and the chip capacitors 160 at the center part.

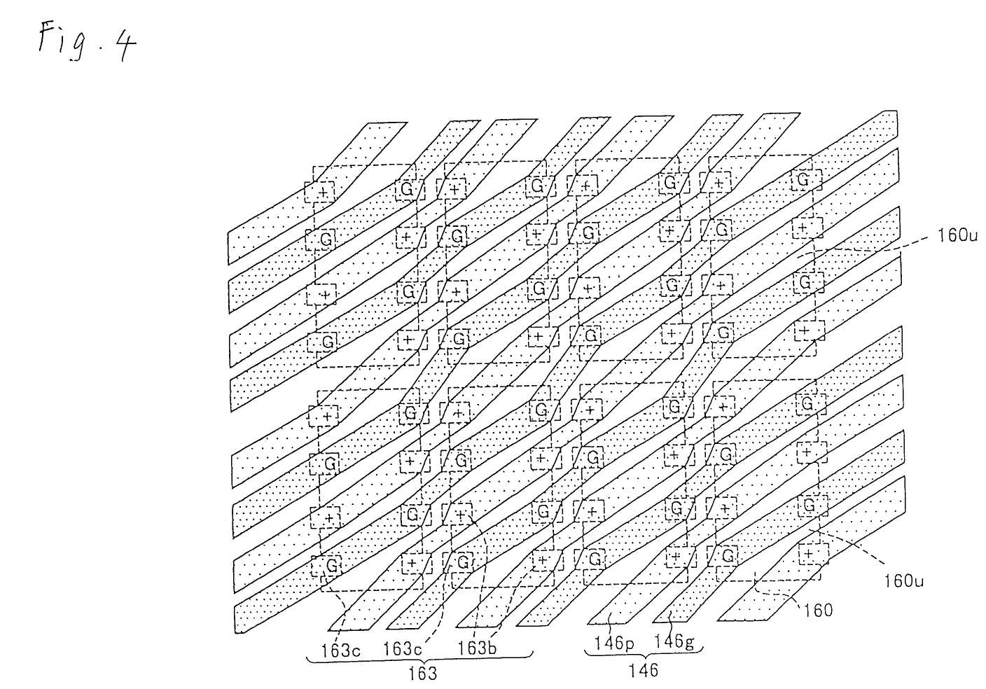

The converting-conductor layers 146 are, as later mentioned (refer to FIG. 4), made patterns of the first converting-conductor layers 146p connected to the +source potential (common first potential) and the second converting-conductor layers 146g connected to the earth potential (common second potential).

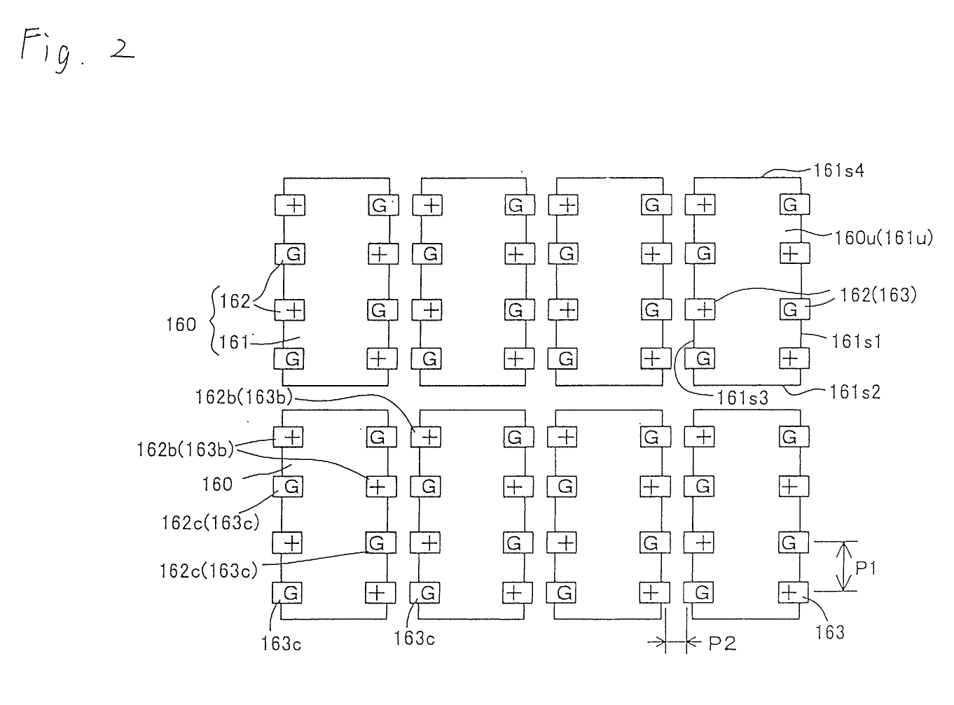

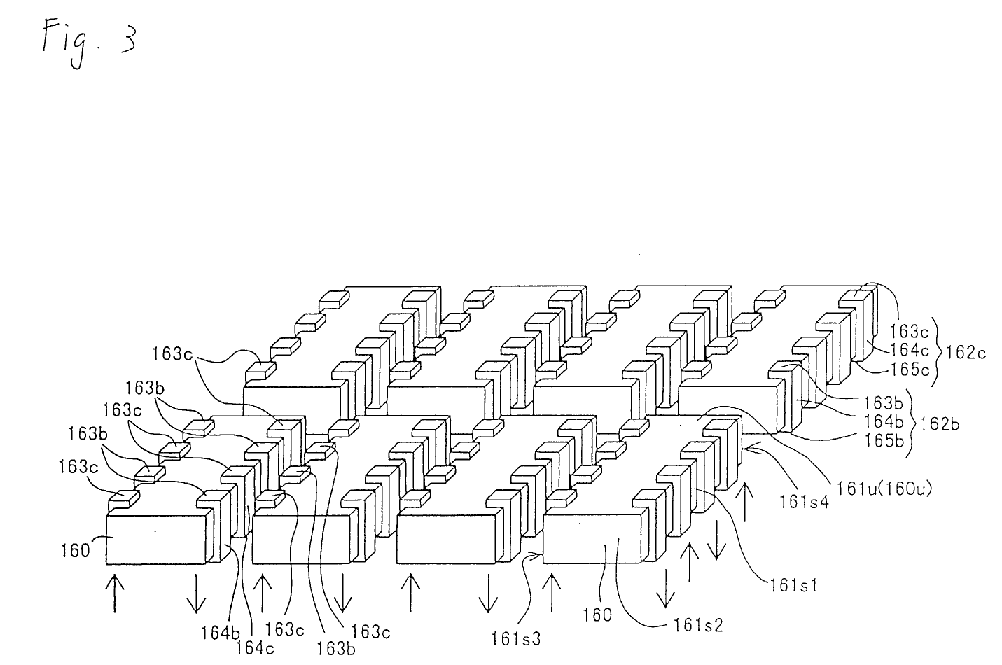

The chip capacitors 160 mounted on the reverse face 101c are, as seen in an enlarged view at the lower part of FIG. 1, FIGS. 2 and 3, laminated ceramic capacitors made of BaTiO3 based high dielectric ceramic. Of them, the capacitor main body 161 is substantially rectangular (3.2×1.6×0.8 mm) having an upper face 161u being a capacitor upper face (first face) 160u directing to a main face 101b of the wiring board main body 101, a lower face 161v being a capacitor lower face 160v directing to a lower face 110b, and four side faces 161s (161s 1, 161s 2, 161s 3, 161s 4) (see FIGS. 2 and 3).

As shown in an enlarge view of FIG. 1, at an interior of the chip capacitor 160, one electrode layers 161e and another electrode layers 161f are many and alternately laminated via the ceramic high dielectric layers 161c parallel to the upper face 161u (vertically along the side face 161s), that is, parallel to the main face 191b. These electrode layers 161e, 161f comprise nickel (Ni). Parts of the electrode layers 161e, 161f are drawn to the first side face 161s1 and the third side face 161s3, and connect with the side face 164 of a terminal 162 of Cu. Specifically, one electrode layer 161e connect with one side face 164b, while the other electrode layer 161f connect with the other side face 164c.

Terminals 162b, 162c have side face parts 164b, 164c respectively positioning on a first side 161s1 and a third side 161s3, and have upper face parts 163b, 163c on an upper face 161u and lower face parts 165b, 165c on a lower face 161v. Therefore, the terminals 162b, 162c go over the periphery of the upper face 161u from the upper face parts 163b, 163c, and extend a side face 161s (side faces 164b, 164c) from an upper face 161u (i.e., a side of a main face 101b) toward a lower face 161v (i.e., a side of a reverse face 101c), and go over the periphery of the lower face 161v to connect with the lower faces 165b, 165c, and thus form substantially U shapes.

The chip capacitor 160 of this embodiment is formed with respective terminals 162 at the first side face 161s1 and the opposite third side face 161s3, while at the second side face 161s2 and the fourth side face 161s4, the terminals 162 are not formed. As shown in FIG. 2, in regard to one chip capacitor 160, seeing clockwise from the first side face 161s1, second side face 161s2, third side face 161s3 and fourth side face 161s4, the terminals 162b, 162c, accordingly, the upper face parts 163b, 163c are arranged alternately. In short, as later mentioned, if either one of the electrode layers 161e and 161f (161e in this embodiment) is the +source potential (shown with “+” in FIG. 2) and the other (161f in this embodiment) is earth potential (shown with “G” in FIG. 2), the terminal 162b (the upper face part 163b) connected to the source potential shown with “+” and the terminal 162c (the upper face part 163c) connected to the earth potential shown with “G” are alternately arranged.

As shown in FIGS. 2 and 3, the chip capacitors 160 are arranged in lattice longitudinally and latitudinally such that the first side face 161s1 and the third side face 161s3 of the adjacent chip capacitors 160 as well as the second side face 161s2 and the fourth side face 161s4 of the same are opposite each other. Therefore, considering the connection of the source potential and the earth potential to the respective chip capacitors 160, as shown in FIG. 2, the mutual side face parts 164 of the adjacent and opposite terminals 162 are other potential, that is, as shown in FIG. 3, the side face part 164b of the source potential of one-side capacitor and the side face part 164c of the earth potential of the other-side capacitor are made adjacent.

Incidentally, if charging and discharging the chip capacitors 160, the current flows along the side face parts 164 of the terminals 162 as shown with arrows in FIGS. 1 and 3. By this current, inductance is created at the side faces 164 extending vertically the side face 161s1. The arrow marks in the same show the current flowing directions when charging. In the case of discharging, the current flowing directions are of course reversed.

Seeing one chip capacitor 160, in the relation of the adjacent side face parts 164, as the potentials to be connected thereto are different, the directions of the current flowing when charging and discharging the chip capacitor are opposite each other. Thus, if positioning the chip capacitors such that the potentials to be connected to the adjacent side parts 164 are different, the inductance of the side face part 164 (the terminal 162) may be reduced by the amount of the mutual inductance created by connection of both.

Besides, seeing the adjacent two chip capacitors 160, also in the relation between the adjacent and opposite side face parts 164, as the potentials to be connected are different, the directions of the current flowing when charging and discharging the chip capacitor are opposite each other. Also herein, the self-inductance may be reduced by the amount of the mutual inductance created by connection of both. Accordingly, as a whole, the inductance may be more lowered.

In addition, in this embodiment, as shown in FIG. 2, the distance (pitch), P2=0.4 mm, between the adjacent side face parts 164 of the adjacent chip capacitors 160 is smaller than the distance (pitch), P1=0.8 mm, between the adjacent side face parts 164 in the chip capacitors 160, so that the connection of the adjacent and opposite side face parts 164 is large, thereby enabling to make the inductance smaller.

Voids are maintained between the mutual chip capacitors 160, and the solder resist layers 142 intervene between the mutual capacitor connecting pads 149, whereby insulation is kept of the mutual side face parts 164.

In the wiring board main body 101 of the embodiment, as shown in FIG. 1, the converting-conductor layers 146 are defined at the interlayer 152 between the core board main body 111 and the reverse face side resin insulating layer. Explanation will be made to the converting-conductor layers 146, the terminals 162b, 162c of the chip capacitors 160, in particular, the upper face parts 163b, 163c, and the through hole conductors 113, referring to FIGS. 4, 5 and 6.

FIG. 4 is a view seeing the chip capacitors 113 in M-M′ cross section of FIGS. 1 and 6 by seeing through (or excepting) the reverse face side insulating layers 141, solder resist layer 142 and capacitor connecting terminals 149 from the principal face side, and therefore a view showing, in N-N′ cross section in FIG. 1, a condition of projecting the converting-conductor layers 146 onto the upper faces 160u from the principal face. The converting-conductor layers 146 include the first converting-conductor layers 146p and the second converting-conductor layers 146g, and as showing by differing the hatching in FIG. 4, the first converting-conductor layers 146p and the second converting-conductor layers 146g are each band-shaped and arranged alternately in striped pattern.

Besides, the first converting-conductor layers 146p position on the upper side (the principal face 101b side) of the terminals 162b (the upper face part 163b) connected to the +source potential among the terminals 162 (the upper face part 163) of the chip capacitors 160, while the second converting-conductor layers 146g position on the upper side (the principal face 101b side) of the terminals 162c (the upper face part 163c) connected to the earth potential. Accordingly, it is sufficient to connect the first converting-conductor layers 146p with the terminals 162b (the upper face part 163b) of the chip capacitors 160 positioning on the lower side (the reverse face 101c side) through the short bear conductors 147 passing the reverse face side resin insulating layer 141 and the first capacitor connecting pads 149p (see FIG.

Similarly, it is sufficient to connect the second converting-conductor layers 146g with the terminals 162c (the upper face part 163c) positioning on the lower side through the short bear conductors 147 passing the reverse face side resin insulating layer 141 and the second capacitor connecting pads 149g.

Therefore, it is possible to lower the resistance and the inductance occurring between the converting-conductor layers 146 and the terminals 162 (the upper face part 163) of the capacitors 160.

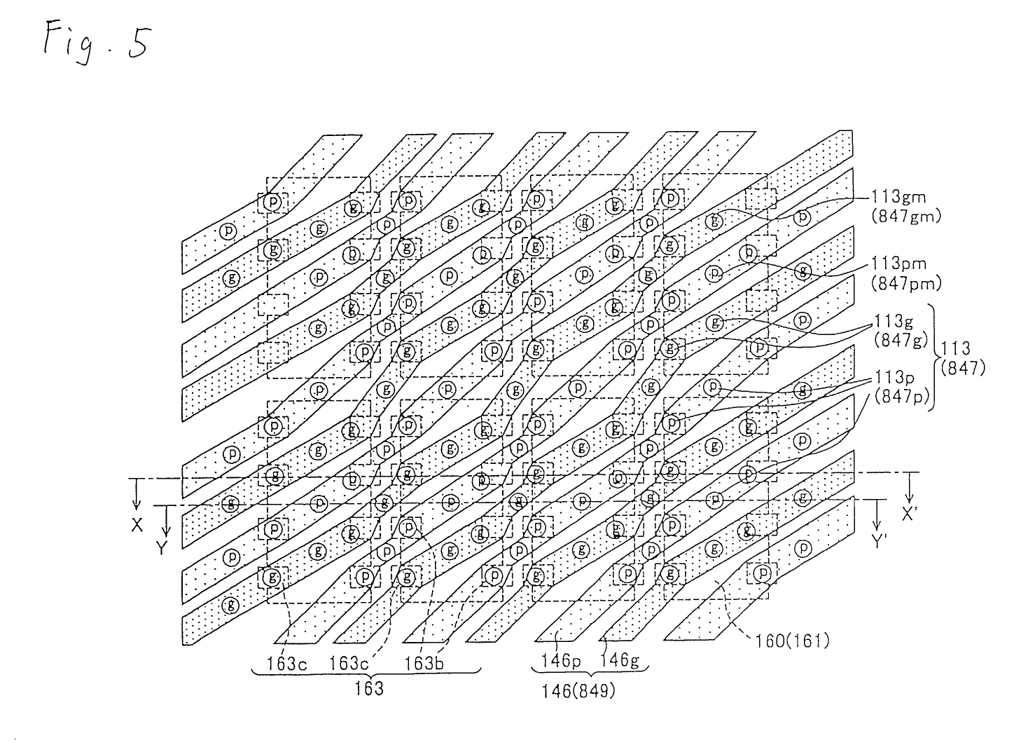

Next explanation will be made to the relation of connecting the converting-conductor layers 146 and the through hole conductors 113 positioning to the principal face side than the converting-conductor layers, referring to FIG. 5. FIG. 5 shows that the first and the second converting-conductor layers 146p, 146g disposed in stripe in FIG. 4 are further overlapped with the connecting positions of the through hole conductors 113 connecting from the principal face side. In FIG. 5, the positions of the through hole conductors 113p connected to the first converting-conductor layers 146p are expressed with ◯ and “p”, while the positions of the through hole conductors 113g connected to the second converting-conductor layers 146g are expressed with ◯ and “g”. As easily comprehending from FIG. 5, in this embodiment, there are some of the through hole conductors 113p, 113g, which respectively connect with the first and second converting-conductor layers 146p, 146g on the upper parts (the principal face 101b side) of the terminals 162b, 162c (the upper face parts 163b, 163c), and there are another some of them, which do not connect thereto on the upper parts of the upper face parts 163b, 163c. The X-X′ cross section of FIG. 5 correspond to that of FIG. 1.

A part between the first converting-conductor layers 146p bridging the two terminals 162b (the upper face part 163b) in the chip capacitors 160, specifically, the through hole conductors 113pm connect with the first converting-conductor layers 146p on the center line when seeing the chip capacitors 160 longitudinally in plane. Similarly, a part between the second converting-conductor layers 146g bridging the two terminals 162c (the upper face part 163c) in the chip capacitors 160, specifically, the through hole conductors 113gm connect with the second converting-conductor layers 146g on the center line when seeing the chip capacitors 160 longitudinally in plane. The Y-Y′ cross section of FIG. 5 correspond to that of FIG. 1.

As the first converting-conductor layers 146p and the second converting-conductor layers 146g are alternately arranged in stripe, for connecting from the bump 129 via the pad 128, the bear conductor 127, the wiring layer 126 and the through hole conductors 113, to the converting-conductor layers 126, it is sufficient to adjust the position by use of the short wiring layers 126, and the connection is easy. Therefore, through the through hole conductors 113, the wiring layers 126, the bear conductors 127 and the pads 128, each of the +source potential and the earth potential can be easily drawn out to the bumps 129, and can connect with the chip capacitors 160 at short distance.

Since the first and the second converting-conductor layers 146p, 146g are each formed at the interlayer 152 between the core board main body 111 and the reverse face side resin insulating layer 141, comparing with a case of using the converting-conductor layers of flat two layers, the number of the necessary interlayer is reduced, so that the resin insulating layer in the wiring board main body 101 can be lessened by the amount of one layer.

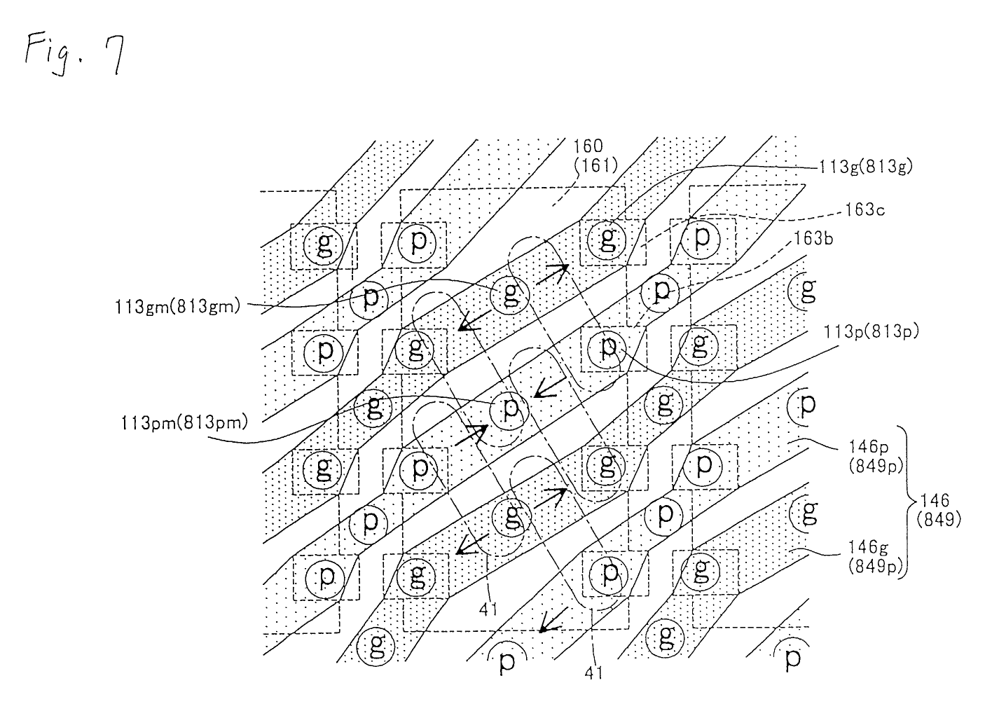

As shown in FIG. 7, a case is considered that the chip capacitors 160 are discharged in the wiring board 100. That is, such a case is considered that the current is caused to flow into IC chip 10 from the terminal 162b (the upper face part 163b) of the source potential of the chip capacitors 160 through the first converting-conductor layers 162p and the through hole conductors 113p, and as a returning path, from IC chip 10, through the through hole conductors 113g and the second converting-conductor layers 146g, the current is caused to flow to the terminal 162c (the upper face part 163c) of the earth potential of the chip capacitors 160. In this case, the arrow marks are given to the current flowing from the first converting-conductor layers 146p into the intermediate connecting through hole conductors 113pm and the current flowing from the intermediate connecting through hole conductors 113pm to the second converting-conductor layers 146g.

In the parts of the revered current encircled with one dotted chain lines in FIG. 7, the direction of the current flowing in the first converting-conductor layers 146p and the direction of the current flowing in the second converting-conductor layers 146g are reversed. Accordingly, it is seen that since the mutual inductances in the parts are negative and can be restrained, the inductance occurring in the whole of the converting-conductor layers 146 and further the wiring board 100 (the wiring board main body 101) can be more lowered.

In this embodiment, as easily understanding from FIGS. 1 and 6, the number of the through hole conductors 113 connected to the converting-conductor layers 146 from the principal face side and the number of the bumps 129 connecting thereto are more than the number of the bear conductors 147 connected to the converting-conductor layers 146 from the reverse face side. Therefore, by furnishing the converting-conductor layers 146 to the interlayer 152, as a whole, resistance and inductance occurring between the chip capacitors 160 and the bumps 129 can be controlled to be lower than a case of furnishing the converting-conductor layers to other interlayer 151.

Further reference will be made to a production method of the wiring board 100 of this embodiment. The embodied wiring board 100 may be formed by a known buildup process of the resin wiring board.

For example, at first, the core board main body 111 is prepared which comprises the composite material of glass-epoxy resin and has lots of penetrating holes 111h passing between the upper face 111b and the lower face 111c. The penetrating holes 111h are bored by, e.g., a drill or a laser.

Then, the core board main body 111 is carried out with Cu plating by a known panel plating process and formed with predetermined patterns through etching, followed by filling a resin 112r into the penetrating holes 111h. By further plating, the through hole conductors 112, 113 are formed in the penetrating holes 111h, and at the same time, the wiring layers 125, 126, 145 of predetermined pattern and the wiring board 146 are formed in the upper face 111b and the lower face 111c of the core board main body.

Then, the principal face side and the reverse face side resin insulating layers 121, 141 are formed by the known buildup insulating layer forming technique, and further the bear conductors 127, 147 passing them, the pads 128 and the connecting pads 148 are formed respectively. The solder resist layers 122, 142 are formed to cover unnecessary parts, and the wiring board main body 101 is completed.

Subsequently, the capacitor connecting pads 149 are in advance coated with a solder paste, followed by mounting the chip capacitors 160 on the reverse side and re-flowing thereon to connect the terminals 162 (mainly, the upper face parts 163) of the chip capacitors 160 and the capacitor connecting pads 149 via the solders 169. In addition, the pads 128 are coated with the solder paste and carried out with the re-flowing at temperatures of not fusing the solder 169 for forming the bumps 129. In this manner, the wiring board 100 is completed.

Since the wiring board 100 is mounted with many chip capacitors 160 on the reverse side 101c, noises can be exactly removed, and besides the plural chip capacitors 160 are connected in parallel, so that the inductance of the whole mounted capacitors can be decreased. Seeing the respective chip capacitors 160, polarities of the adjacent and opposite terminals are different, and the directions of the currents flowing are reversed. Therefore, the inductance can be more decreased, and it is possible to connect IC chips 10 and the capacitors 160 at lower inductance.

As the terminals 162 of the chip capacitors 160 are formed with the upper face parts 163b, 163c, the connection is made easy between the capacitor connecting pads 149 formed at the reverse face 101c-side of the wiring board main body 101 and the terminals 162 (the upper face parts 163b, 163c). As the converting-conductor layers, the first converting-conductor layer 146p and the converting-conductor layer 146g are formed at the same interlayer, so that the number of the resin insulating layers can be decreased. Accordingly, the cost-down can be attained.

(Modified Embodiment 1)

The converting-conductor layers 146 of the above embodiment, as shown in FIG. 4 and others, meander in zigzag, but the first and the second converting-conductor layers 146p, 146g of almost straight band are alternate to make stripe-patterns, and other stripe-patterns are also enough.

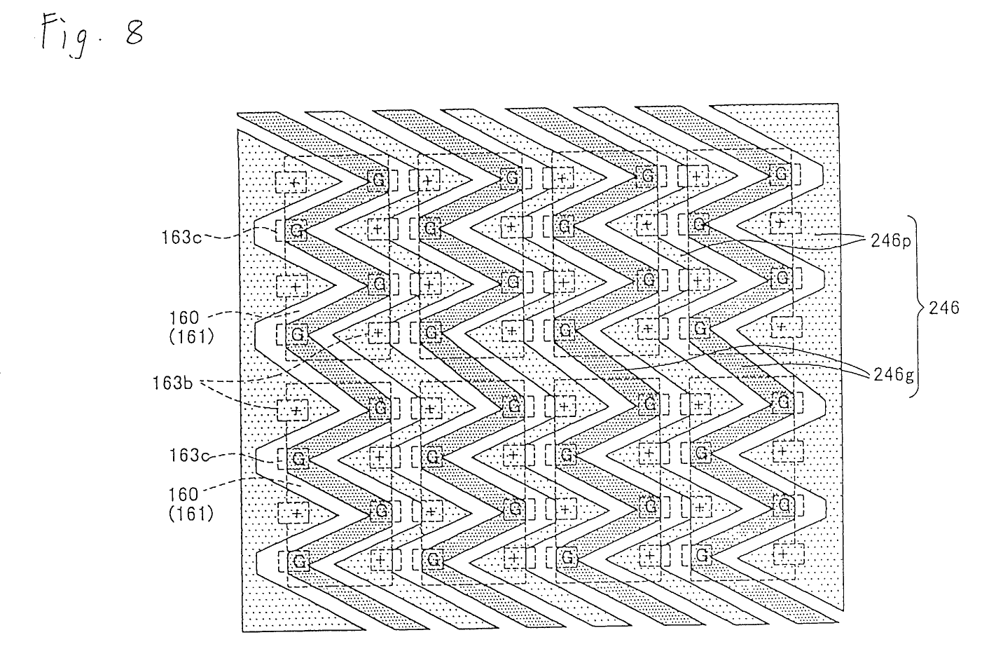

For example, FIG. 8 shows the relation between the first and the second converting-conductor layers 246p, 246g of this modified embodiment 1 and the upper face parts 163b, 163c of the terminals 162 of the chip capacitors 160. In this modified embodiment, as easily comprehending from FIG. 8, the first and the second converting-conductor layers 246p, 246g are made zigzag bands and are alternately arranged in stripe patterns.

The converting-conductor layers 246 are made such patterns, and similarly to the embodiment 1, the upper face parts 163b, 163c of the chip capacitors 160 are respectively positioned at the lower part (the reverse side) of the first and the second converting-conductor layers 246p, 246g, and similarly to the embodiment 1, the connection is made by the short bear conductors 147 and the capacitor connecting pads 149. Also in the principal face side of the converting-conductor layer 246, the connection can be easily made with the through hole conductor 113 (see FIG. 1).

Therefore, depending on the converting-conductor layer 246, the chip capacitor 160 and the bump 129 (the connecting terminal 12 of IC chip 10) are easily connected.

(Modified Embodiment 2)

In the above embodiment and the modified embodiment 1, among the four side faces 161s1 to 161s4 of the chip capacitors 160, the first side face 161s1 and the third side face 161s3 are formed with terminals 162, and other modified chip capacitors may be employed.

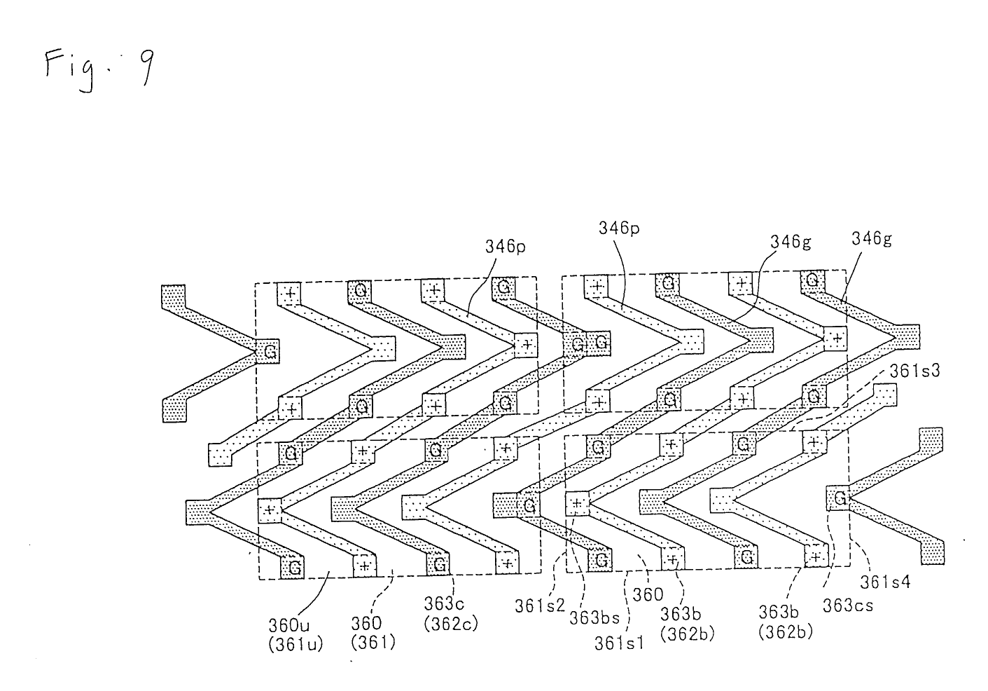

For example, as shown in FIG. 9, the chip capacitor 360 used in the present modified embodiment 2 is, similarly to the chip capacitor 160 of the embodiment 1, formed with terminals 362b, 362c (the upper face parts 363b, 363c) in the first side face 361s1 and the third side face 361s3, and with terminals 362 (the upper face parts 363bs, 363cs) in the second side face 361s2 and the fourth side face 361s4.

When using such chip capacitors 360, as shown in FIG. 9, the first and the second converting-conductor layers 346p, 346g are alternately arranged in zigzag like stripes, so that the respective upper face parts 363b, 363c (including 363bs, 363cs) can be positioned at the lower parts of the first and the second converting-conductor layers 346p, 346g, and similarly to the embodiment 1, both can be connected with the short bear conductors 147. Also in the principal face side of the converting-conductor layer 346, the connection can be easily made with the through hole conductor 113 (see FIG. 1).

Therefore, depending on the converting-conductor layer 346, the chip capacitor 360 and the bump 129 (the connecting terminal 12 of IC chip 10) are easily connected.

(Modified Embodiment 3)

Further, using the chip capacitors 360 in the above modified embodiment 2, the first and the second converting-conductor layers can be made other striped patterns.

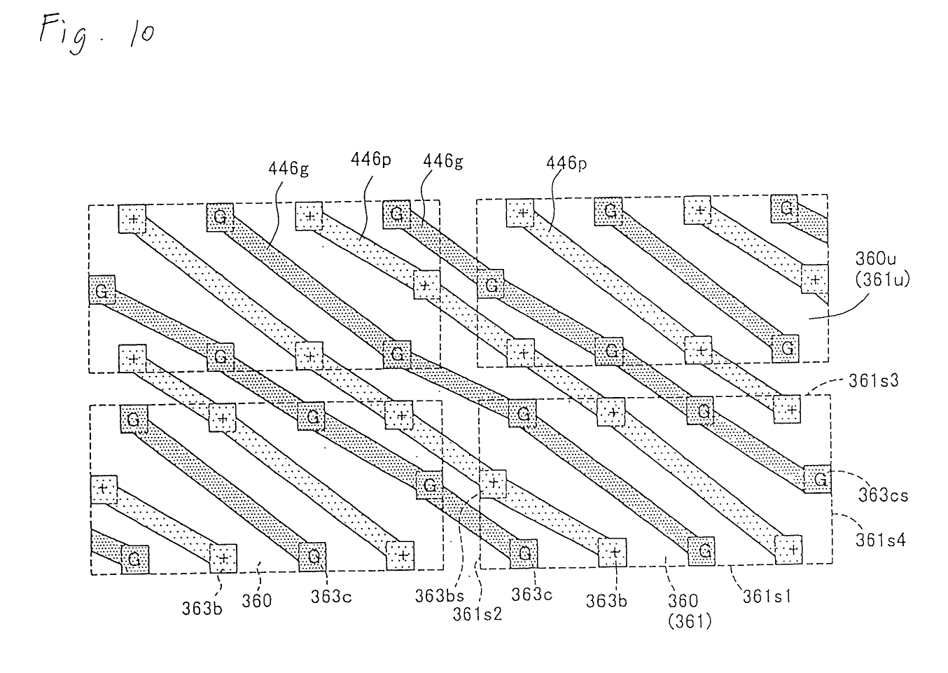

For example, FIG. 10 shows the relation between the first and the second converting-conductor layers 446p, 446g of this modified embodiment 3 and the upper face parts 363b, 363c of the terminals 362 of the chip capacitors 360. In this modified embodiment 3, as easily comprehending from FIG. 10, the first and the second converting-conductor layers 446p, 446g are almost straight and are alternately arranged in stripe patterns. Similarly to the modified embodiment 2, the upper face parts 363b, 363c are positioned at the lower parts of the first and the second converting-conductor layers 446p, 446g, and similarly to the embodiment 2, both can be connected with the short bear conductors 147. Also in the principal face side of the converting-conductor layer 446, the connection can be easily made with the through hole conductor 113 (see FIG. 1).

Therefore, depending on the converting-conductor layer 446, the chip capacitor 360 and the bump 129 (the connecting terminal 12 of IC chip 10) are easily connected.

(Modified Embodiment 4)

In the embodiment and the modified embodiments 1 to 3, the terminals 162, 362 of the chip capacitors are formed at the side faces, having the upper face parts 163, 363 going around to the upper parts. But the chip capacitor usable in the invention is enough with such embodiments that the terminal is formed on the upper face of the chip capacitor and can be connected at the upper part (the principal face side) or the terminal is formed in bump.

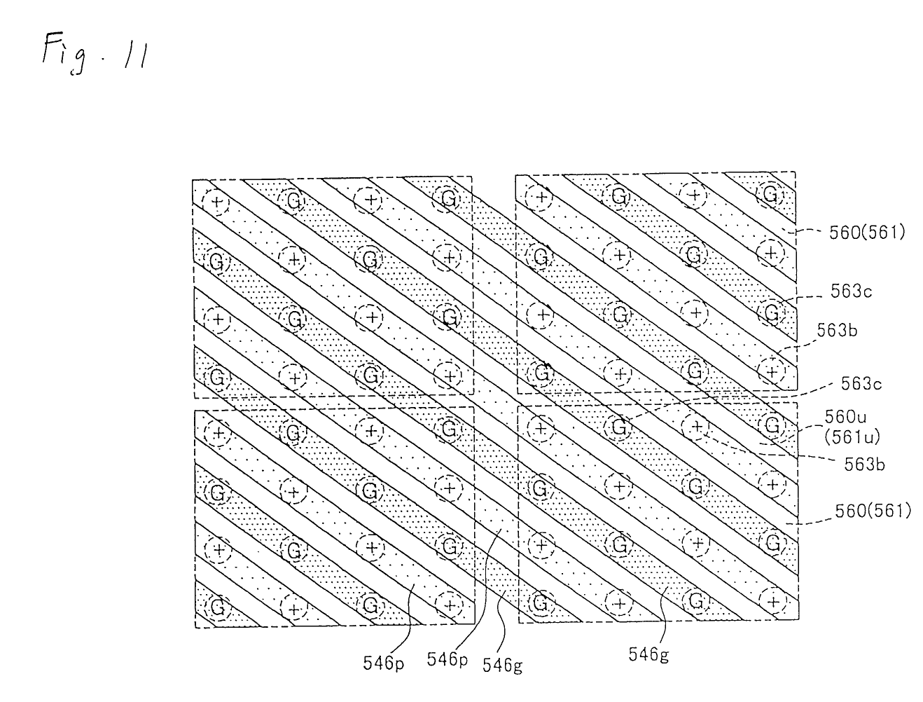

For example, as shown in FIG. 11, being different from the chip capacitor 160 of the embodiment, the chip capacitors 560 used in the modified embodiment 4 have the terminals 563 arranged in lattice longitudinally and latitudinally on the upper face 560u (the upper face 561u of the chip capacitor main body). Besides, the first terminals 563b connected to the +source potential and the second terminals 563c connected to the earth potential are alternately placed. When using such chip capacitors 560, as shown in FIG. 11, the first and the second converting-conductor layers in straight band-like arrangement are alternately located to form stripe, so that the respective terminals 563b, 563c can be positioned under the first and the second converting-conductor layers 546p, 546g, and similarly to the embodiment 1, the connection is made by the short bear conductors 147 and the capacitor connecting pads 149. Also in the principal face side of the converting-conductor layer 546, the connection can be easily made with the through hole conductor 113 (see FIG. 1).

Therefore, depending on the converting-conductor layer 546, the chip capacitor 560 and the bump 129 (the connecting terminal 12 of IC chip 10) are easily connected.

(Modified Embodiment 5)

Further, using the chip capacitors 560 in the above modified embodiment 4, the first and the second converting-conductor layers can be made other striped patterns.

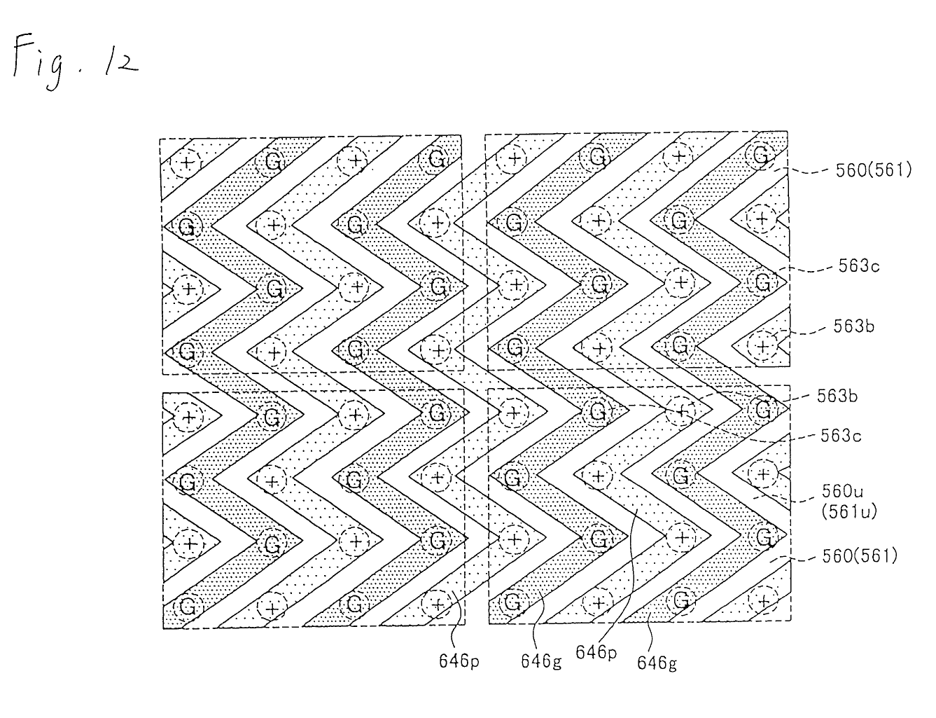

For example, FIG. 12 shows the relation between the first and the second converting-conductor layers 646p, 646g of this modified embodiment 4 and the terminals 563b, 563c of the chip capacitors 560. In this modified embodiment 5, as easily comprehending from FIG. 12, the first and the second converting-conductor layers 646p, 646g are zigzag-band shaped and are alternately arranged in stripe patterns. Further, similarly to the modified embodiment 4, the respective terminals 563b, 563c are positioned under the first and the second converting-conductor layers 646p, 646g. Similarly to the modified embodiment 4, the connection is made by the short bear conductors 147 and the capacitor connecting pads 149. Also in the principal face side of the converting-conductor layer 646, the connection can be easily made with the through hole conductor 113 (see FIG. 1)

Therefore, also depending on the converting-conductor layer 646, the chip capacitor 560 and the bump 129 (the connecting terminal 12 of IC chip 10) are easily connected.

(Embodiment 2)

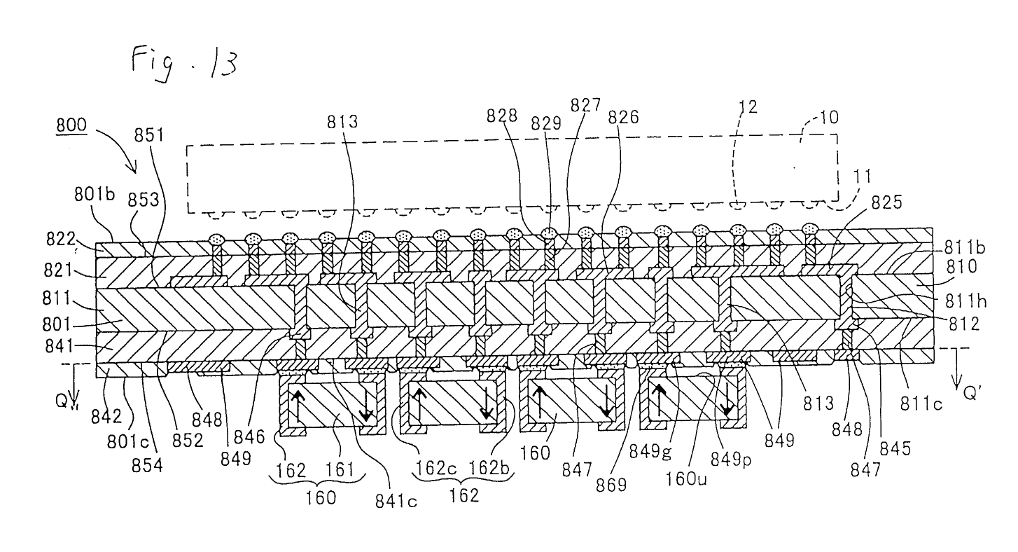

Explanation will be made to a second embodiment of the invention, referring to FIGS. 13 to 15. A wiring board 800 of this embodiment has substantially the same structure as the wiring board 100. But in the wiring board 100 of the embodiment 1, the converting-conductor layers 146 (the first and the second converting-conductor layers 146p, 146g) of stripe pattern are defined with the interlayer 152 between the core board main body 111 and the reverse face side resin insulating layer 141. On the other hand, this embodiment 2 is different in that the converting-conductor layers 849 (the first and the second converting-conductor layers 849p, 849g) of almost the same shape as that of the converting-conductor layer 146 are formed in the reverse side 841c of the reverse face side resin insulating layer 841, that is, at the interlayer 854 between the reverse face side resin insulating layer 841 and the solder resist layer 842. Therefore, different parts will be mainly explained by omitting or simplifying the similar parts.

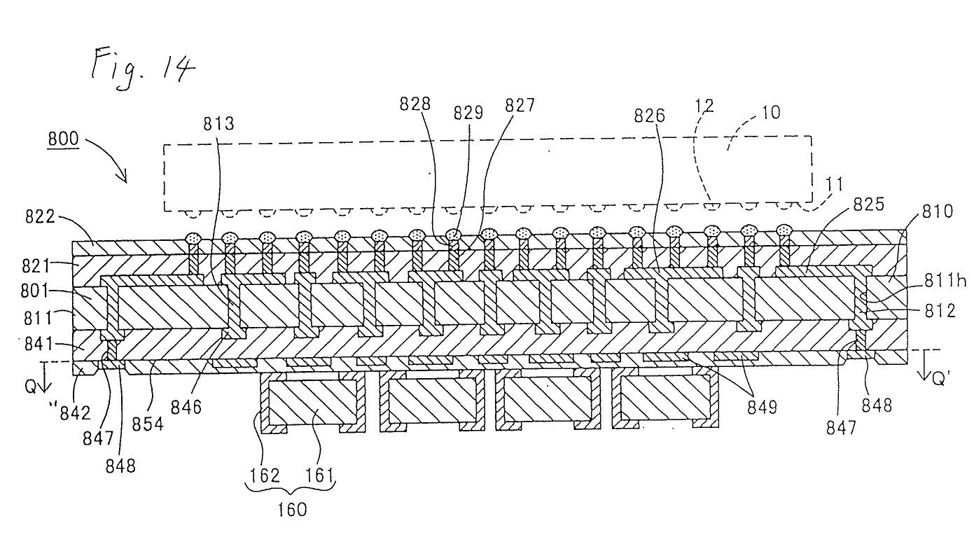

The wiring board 800 shown in FIGS. 13 and 14 comprises a wiring board main body 801 and the chip capacitors 160 mounted on a reverse face 801c and similar to that of the embodiment 1. The wiring board 801 has, similarly to the embodiment 1, a core board 810, a principal face side resin insulating layer 821 and a solder resist layer 822 laminated on the upper and lower surfaces thereof, a reverse face side resin insulating layer 841 and a solder resist layer 842. On the center part of the principal face 801b of the wiring board main body 801, lots of bumps 829 are formed and make flip-chip connections with many connecting terminals 12 formed on the under surface 11 of IC chip 10 shown with an imaginary line. On the center part of the reverse face 801c, lots of capacitor connecting pads 849 are formed on which the chip capacitors 160 are many mounted via solders 869. At the periphery of the reverse face 801c, connecting pads 848 are formed.

The core board 810 has a core board main body 811 similarly to the embodiment 1. Between an upper surface 811b and a lower surface 811c, many through hole penetrating holes 811h are bored passing therethrough. Known through hole conductors 112, 113 are defined at the interior thereof.

The bumps 829 are connected to wiring layers 825, 826 formed on the upper surface 811b of the core board main body 111 (the interlayer 851 of the core board main body 811 and the principal face side resin insulating layer 821) via the pads 828 opening to the solder resist layer 822 and the bear conductors 827 penetrating the principal face side resin insulating layer 821.

Specifically, the bumps 829 positioned almost on the peripheral part connect with the wiring layers 825 through pads 828 and the bear conductors 827, respectively fan out to the peripheral side (the right or left directions in FIGS. 13 and 14), connect with the through hole conductors 812 positioned on the peripheral part and further connect with the connecting pads 848 exposed from the solder resist layer 842 via the wiring layers 845 formed in the reverse face 811c (the interlayer 852) and the bear conductors 847. These members are mainly served as wiring for signals, and sometimes served as source wiring for supplying the +source potential and the earth potential.

On the other hand, the bumps 829 positioned almost on the center do not fan out, but adjust the positions by use of the wiring layers 826 formed at the interlayer 851, otherwise converge the wires (the bear conductors) from the plural bumps 829, that is, connect in parallel them, and connect with the through hole conductors 813 positioning at the center. Until here, the conditions are the same as in the embodiment 1.

Further, the through hole conductors 813 connect with the wiring layer 846 formed on the lower face 811c (the interlayer 852) of the core board 811, and connect with the wiring board 849 formed on the reverse face 841c (the interlayer 854) of the reverse face side resin insulating layer 841 through the bear conductors 847 penetrating the reverse face side resin insulating layer 841. Parts of the wiring boards 849 are exposed from the solder resist layers 842, and connect with the terminals 162 (162b, 162c) of the chip capacitors 160 by means of the solder 869. In short, the converting-conductor layers 849 are formed at the reverse face side 841c of the most-reverse face side insulating layers 841 among the insulating layers (the principal face side resin insulating layer 821, the core board main body 811 and the reverse face side resin insulating layer 841) intervening between the bumps 829 and the terminals 162 of the chip capacitors 160.

In such a manner, the electrodes 162 (162b, 162c) of the chip capacitors 160 and the bumps 829 are connected.

As seen at the left side of FIG. 13, some of the connecting pads 848 positioning on the periphery of the reverse face 801c connect with the converting-conductor layers 849 at the reverse face 841c of the reverse face side resin insulating layer 841, and through such courses, the +source potential and earth potential are supplied respectively into the bumps 829 and the chip capacitors 160 at the center part. Otherwise, through the course of the connecting pad 848, the bear conductor 847, the wiring layer 845, the through hole conductor 812 and the wiring layers 825, 826, the +source potential and earth potential can be also supplied respectively into the bumps 829 and the chip capacitors 860 at the center part.

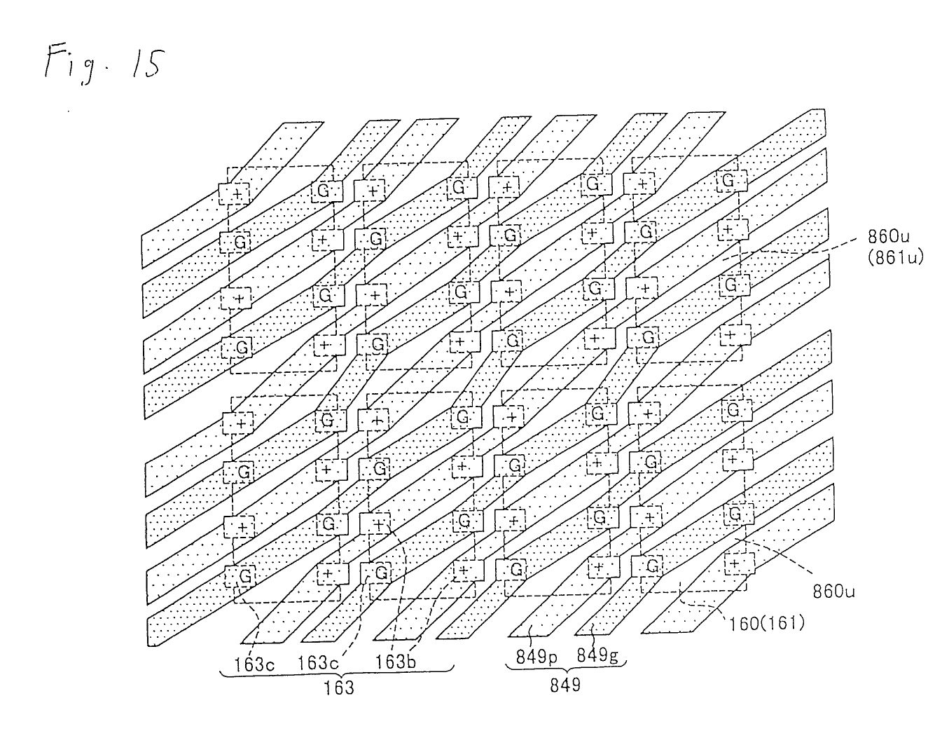

The converting-conductor layers 849 have, as shown in FIG. 15, almost the same patterns as those of the converting-conductor layers 146 of the embodiment 1, and are made patterns of the first converting-conductor layers 849p connected to the +source potential (common first potential) and the second converting-conductor layers 849g connected to the earth potential (common second potential).

But the converting-conductor layer 849 is different in that triangular projections are formed, in comparison with the converting-conductor layer 146 shown in FIG. 4, for simplifying the connection by coping with the shapes of the terminals 162 (the upper face part 163) of the reverse face side 160. FIG. 15 is a view seeing the chip capacitors 113 in Q-Q′ cross section of FIGS. 13 and 14 by seeing through (or excepting) the solder resist layer 842 and the solder 869 from the principal face side, and shows the relation between the converting-conductor layer 849 and the terminals 162b, 162c (the upper face parts 163b, 163c) of the chip capacitor 160.

As easily understanding from FIG. 15, each of the first converting-conductor layers 849p is positioned on the upper side (the principal face 801b-side) of the terminals 162b (the upper face part 163b) connected to the +source potential among of the terminals 162 (the upper face part 163) of the chip capacitors 160, and each of the first converting-conductor layers 849g is positioned on the upper side (the principal face 801b-side) of the terminals 162c (the upper face part 163c) connected to the earth potential. Accordingly, it is possible to easily connect the first converting-conductor layers 849p with the terminals 162b (the upper face part 163b) of the chip capacitors 160 positioning on the lower side (the reverse face 801c-side) by the solder 869 (see FIG. 13).

Similarly, it is possible to easily connect the second converting-conductor layers 849g with the terminals 162c (the upper face part 163c) positioning on the lower side thereof by the solder 869.

Therefore, it is possible to control the resistance and the inductance occurring between the converting-conductor layers 849 and the terminals 162 of the capacitors 160.

The relation of connecting the converting-conductor layers 849 and the bear conductors positioning to the principal face side than the converting-conductor layers, is the same as the relation between the converting-conductor layer 146 and the through hole conductor 113 in the embodiment 1 explained referring to FIG. 5. That is, as easily comprehending from FIG. 5, also in this embodiment, there are some of the bear conductors 847p, 847g, which respectively connect with the first and second converting-conductor layers 146p, 146g on the upper parts (the principal face 101b side) of the terminals 862b, 862c (the upper face parts 863b, 863c), and there are another some of them, which do not connect thereto on the upper parts of the upper face parts 863b, 863c. The X-X′ cross section of FIG. 5 correspond to that of FIG. 13. FIG. 5 shows the embodiment of the converting-conductor layer 146 of the embodiment 1 as the shape of the converting-conductor layer, which is somewhat different from the embodiment of the converting-conductor layer 146 shown in FIG. 15.

Apart between the first converting-conductor layers 849p bridging the two terminals 162b (the upper face part 163b) in the chip capacitors 160, specifically, the intermediate connecting bear conductors 847pm connect with the first converting-conductor layers 849p on the center line when seeing the chip capacitors 160 longitudinally in plane. Similarly, a part between the second converting-conductor layers 849g bridging the two terminals 162c (the upper face part 163c) in the chip capacitors 160, specifically, the intermediate connecting bear conductors 847gm connect with the second converting-conductor layers 849g on the center line when seeing the chip capacitors 160 longitudinally in plane (see FIG. 5).

As the first converting-conductor layers 849p and the second converting-conductor layers 849g are alternately arranged in stripe, for connecting from the bump 129, via the pad 828, the bear conductor 827, the wiring layer 826, the through hole conductors 813, the wiring layer 846 and the bear conductor 847, to the converting-conductor layers 849, it is sufficient to adjust the position by use of the short wiring layers 826, and the connection is easy. Therefore, through them, each of the +source potential and the earth potential can be easily drawn out to the bumps 829, and can connect with the chip capacitors 160 at short distance.

Since the first and the second converting-conductor layers 849p, 849g are each formed at the reverse face side 841c of the reverse face side resin insulating layer 841, and comparing with a case of using the converting-conductor layers of flat two layers, the number of the necessary interlayer is reduced, so that the resin insulating layer in the wiring board main body 801 can be lessened by the amount of one layer.

As shown in the wiring board 800, the same explanation in the embodiment 1 with reference to FIG. 7 is also applied to the current flowing in the converting-conductor layer 849 when charging and discharging the chip capacitor 160. That is, the case is considered that the chip capacitors 160 are discharged in the wiring board 800. In the parts of the revered current encircled with one dotted chain lines in FIG. 7, the direction of the current flowing in the first converting-conductor layers 849p and the direction of the current flowing in the second converting-conductor layers 146g are reversed. Accordingly, it is seen that since the mutual inductances in the parts are negative and can be restrained, the inductance occurring in the whole of the converting-conductor layers 849 and further the wiring board 800 (the wiring board main body 801) can be more lowered.

In this embodiment, as easily understanding from FIGS. 13 and 14, the number of the bear conductors 847 connected to the converting-conductor layers 849 from the principal face side and the number of the bumps 129 connecting thereto are more than the number of the terminals of the chip capacitors 160 connected to the converting-conductor layers 849 from the reverse face side. Therefore, by furnishing the converting-conductor layers 849 to the reverse face of the reverse face side insulating layer 841 nearest to the chip capacitor 160, in comparison with cases of furnishing the converting-conductor layers to the interlayer 151 or 152, resistance and inductance occurring particularly between the chip capacitors 160 and the bumps 129 can be controlled to be lower.

By the way, the production method of the wiring board 800 of the embodiment 2 may depend on the known buildup process similarly to the wiring board 100 of the embodiment 1, and so explanation will be omitted.

Since the wiring board 800 is also mounted with many chip capacitors 160 on the reverse side 801c, noises can be exactly removed, and besides the plural chip capacitors 160 are connected in parallel, so that the inductance of the whole mounted capacitors can be decreased. Seeing the respective chip capacitors 160, polarities of the adjacent and opposite terminals are different, and the directions of the currents flowing are reversed. Therefore, the inductance can be more decreased, and it is possible to connect IC chips 10 and the capacitors 160 at lower inductance.

As the terminals 162 of the chip capacitors 160 are formed with the upper face parts 163b, 163c, the connection is made easy between the converting-conductor layer 849 and the terminals 162 (the upper face parts 163b, 163c) As the converting-conductor layers, the first converting-conductor layer 849p and the second converting-conductor layer 849g are formed at the reverse face 841c (the interlayer 852) of the same reverse face side resin insulating layer 841, so that the number of the resin insulating layers can be decreased. Accordingly, the cost-down can be attained.

In the above mentioned description, the invention has been explained in the embodiments 1, 2 and the modified embodiments 1 to 5, but the invention is not limited thereto, and so far as not getting out the subject matter, modifications may be applied.

For example, in the embodiments 1 and 2, the solder resist layers 122, 142, 822, 842 are formed respectively at the upper part of the principal face side resin insulating layer (IC chip side) and at the lower part of the reverse face side insulating layer (the chip capacitor side), but a wiring board of such an embodiment without forming the solder resist layer is sufficient.

Further, in the embodiments 1 and 2, the principal face side and reverse face side insulating layers 121, 141, 821, 841 are formed one by one layer on and under the core board main bodies 111, 811, but the embodiments may be applied to the wiring board laminated with more resin insulating layers.

The embodiments 1 and 2 show the examples that the source potential or the earth potential are supplied to the chip capacitors 160 and the bumps 129, 829 via the connecting pads 148 formed on the peripheral parts of the reverse faces 101c, 801c from the mother board (not shown). However, it is sufficient that the terminals 162 (the lower face part 164) of the chip capacitor 160 and the terminals of the mother board are directly connected for supplying the source potential or the earth potential to the chip capacitors 160 and the bumps 129, 829.

The embodiments and the modified embodiments exemplify that the first converting-conductor layers and the second converting-conductor layers are alternately arranged in stripe pattern all over the converting-conductor layers, but the stripe pattern is enough with one part.

In the embodiment 2, the pattern of the converting-conductor layer 849 is the same as that of the embodiment 1. Also in the wiring board 800 shown in the embodiment 2, the pattern of the converting-conductor layer 849 may be another one, for example, the pattern of the modified embodiment 1 is available. In addition, as the chip capacitors and the patterns of the converting-conductor layer for the embodiment 2, the chip capacitors and the patterns of the converting-conductor layer shown in the modified embodiments 2, 3, 4, 5 may be served, and thus, embodiments of the chip capacitor may be appropriately modified.

The embodiments 1 and 2 show the center insulating layer such as the wiring board 100 using the core board main bodies 111, 811, but the invention can be applied to wiring boards without using the core board main body.

In the embodiments 1 and 2, the converting-conductor layer layers 146, 849 are formed on the reverse face side (the lower side of the drawings) of the core board main bodies 111, 811, but the converting-conductor layers may be formed on the principal face side (the center part of the drawings), e.g., on the upper face 111b of the core board main body, otherwise at the interlayer of the principal face side resin insulating layers or between the principal face side resin insulating layer and the solder resist layer.

The embodiments 1 and 2 show that the distance between the through hole conductors 113 formed on the core board main body 111 is larger than the distance between the bumps 129, 829, but the invention can be applied to the case of the same distance of both.

In the embodiment 2, the positions of the bear conductor 827 and the through hole conductor 813 are adjusted by means of the wiring layer 826 formed on the upper face 811b (the interlayer 151) of the core board main body 811, thereby to make the positional adjustment of the through hole conductor 813 and the bear conductor 847 unnecessary, and the bear conductor 847 is connected to the converting-conductor layer 849. But, by means of the wiring layer 846, the positional adjustment of the through hole conductor 813 and the bear conductor 847 may be performed, and by both of the wiring layer 826 and 846, the positional adjustment may be carried out.

This application is based on Japanese Patent application JP 2000-402498, filed Dec. 28, 2000, the entire content of which is hereby incorporated by reference, the same as if set forth at length.

What is claimed is:

1. A wiring board having a principal face and a reverse face, which comprises:
i) a plurality of principal-face-side connecting terminals formed on the principal face side, wherein the principal-face-side connecting terminals are capable of being connected to terminals, respectively, of an electronic part to be mounted on the principal face side;
ii) at least one chip capacitor having an one-side electrode and an other-side electrode, wherein the chip capacitor is mounted on the reverse face side, and comprises: a first face facing to the reverse face; at least one first terminal that is formed on the first face and connected to the one-side electrode; and at least one second terminal that is formed on the first face and connected to the other-side electrode;
iii) at least one first capacitor-connecting terminal formed on the reverse face side, wherein the first capacitor-connecting terminal is connected to the first terminal;
iv) at least one second capacitor-connecting terminal formed on the reverse face side, wherein the second capacitor-connecting terminal is connected to the second terminal;
v) a plurality of insulating layers interposed between the principal-face-side connecting terminals, and the at least one first capacitor-connecting terminal and the at least one second capacitor-connecting terminal disposed on the reverse side;
vi) at least one first converting-conductor layer formed at an interlayer between adjacent two insulating layers, wherein the first converting-conductor layer is electrically connected to a plurality of the principal-face-side connecting terminals at the principal face side, is electrically connected to at least one of the first capacitor-connecting terminals at the reverse face side, and converts a connecting position and a connecting number between the principal-face-side connecting terminal and the first capacitor-connecting terminal at the principal face side and the reverse face side; and
vii) at least one second converting-conductor layer formed at the interlayer, wherein the second converting-conductor layer is insulated from the first converting-conductor layer, is electrically connected to a plurality of the principal-face-side connecting terminals at the principal face side, is electrically connected to at least one of the second capacitor-connecting terminals at the reverse face side, and converts a connecting position and a connecting number between the principal-face-side connecting terminal and the second capacitor-connecting terminal at the principal face side and at the reverse face side.

2. The wiring board according to claim 1, wherein the interlayer is an interlayer nearest to the at least one first capacitor-connecting terminal and the at least one second capacitor-connecting terminal, and the number of the principal-face-side connecting terminals electrically connected to one of the first converting-conductor layer and the second converting-conductor layer is more than the sum of: the number of the first capacitor-connecting terminal electrically connected to the first converting-conductor layer; and the number of the second capacitor-connecting terminal electrically connected to the second converting-conductor layer.

3. The wiring board according to claim 1, wherein the first capacitor-connecting terminal electrically connected to the first converting-conductor layer from the reverse face side is positioned at least partly within a region formed by projecting the first converting-conductor layer in the direction of the first face,
the first capacitor-connecting terminal and the first converting-conductor layer are connected through a bear conductor passing through the insulating layers,
the second capacitor-connecting terminal electrically connected to the second converting-conductor layer from the reverse face side is positioned at least partly within a region formed by projecting the second converting-conductor layer in the direction of the first face, and
the second capacitor-connecting terminal and the second converting-conductor layer are connected through a bear conductor passing through the insulating layers.

4. The wiring board according to claim 2, wherein the first capacitor-connecting terminal electrically connected to the first converting-conductor layer from the reverse face side is positioned at least partly within a region formed by projecting the first converting-conductor layer in the direction of the first face,
the first capacitor-connecting terminal and the first converting-conductor layer are connected through a bear conductor passing through the insulating layers,
the second capacitor-connecting terminal electrically connected to the second converting-conductor layer from the reverse face side is positioned at least partly within a region formed by projecting the second converting-conductor layer in the direction of the first face, and
the second capacitor-connecting terminal and the second converting-conductor layer are connected through a bear conductor passing through the insulating layers.

5. A wiring board having a principal face and a reverse face, which comprises:
i) a plurality of principal-face-side connecting terminals formed on the principal face side, wherein the principal-face-side connecting terminals are capable of being connected to terminals, respectively, of an electronic part to be mounted on the principal face side;
ii) at least one chip capacitor having an one-side electrode and an other-side electrode, wherein the chip capacitor is mounted on the reverse face side, and comprises: a first face facing to the reverse face; at least one first terminal that is formed on the first face and connected to the one-side electrode; and at least one second terminal that is formed on the first face and connected to the other-side electrode;
iii) a plurality of insulating layers interposed between the principal-face-side connecting terminals, and the at least one first terminal and the at least one second terminal, the insulating layers comprising a most-reverse face side insulating layer that is a layer nearest to the reverse face;
iv) at least one first converting-conductor layer formed on a surface of the most-reverse face side insulating layer, the surface facing to the reverse face, wherein the first converting-conductor layer is electrically connected to a plurality of the principal-face-side connecting terminals at the principal face side, is connected or is electrically connected through a conductive connecting material to at least one of the first terminals at the reverse face side, and converts a connecting position and a connecting number between the principal-face-side connecting terminal and the first terminal at the principal face side and at the reverse face side; and
v) at least one second converting-conductor layer formed on the surface, wherein the second converting-conductor layer is insulated from the first converting-conductor layer, is electrically connected to a plurality of the principal-face-side connecting terminals at the principal face side, is connected or is electrically connected through a conductive connecting material to at least one of the second terminals at the reverse face side, and converts a connecting position and a connecting number between the principal-face-side connecting terminal and the second terminal at the principal face side and at the reverse face side.

6. The wiring board according to claim 5, wherein the number of the principal-face-side connecting terminals electrically connected to one of the first converting-conductor layer and the second converting-conductor layer is more than the sum of: the number of the first terminal electrically connected to the first converting-conductor layer; and the number of the second terminal electrically connected to the second converting-conductor layer.

7. The wiring board according to claim 1, wherein the first converting-conductor layer and the second converting-conductor layer are alternately arranged so as to form a stripe pattern.

8. The wiring board according to claim 5, wherein the first converting-conductor layer and the second converting-conductor layer are alternately arranged so as to form a stripe pattern.

9. The wiring board according to claim 7, wherein, in the stripe pattern, the current flowing of the first converting-conductor layer is opposite to the current flowing of the second converting-conductor layer in the direction at the time that the chip capacitor charges or discharges.

10. The wiring board according to claim 8, wherein, in the stripe pattern, the current flowing of the first converting-conductor layer is opposite to the current flowing of the second converting-conductor layer in the direction at the time that the chip capacitor charges or discharges.

11. The wiring board according to claim 1, wherein layer of the one-side electrode and layers of the other-side electrode are alternately laminated parallel to the first face, via a high dielectric ceramic layer.

12. The wiring board according to claim 5, wherein layer of the one-side electrode and layers of the other-side electrode are alternately laminated parallel to the first face, via a high dielectric ceramic layer.
